(19) United States
(12) Patent Application Publication
(10) Pub. No.: US 2025/0011922 A1
(43) Pub. Date: Jan. 9, 2025

(54) DIAMOND FORMATION DEVICE AND DIAMOND-COATED SUBSTRATE

(71) Applicants: NATIONAL UNIVERSITY CORPORATION EHIME UNIVERSITY, Matsuyama-shi, Ehime (JP); GROWTH CO., LTD., Osaka-shi, Osaka (JP)

(72) Inventors: Hiromichi TOYOTA, Matsuyama-shi, Ehime (JP); Ryoya SHIRAISHI, Matsuyama-shi, Ehime (JP); Toshiyuki SHIMADA, Osaka-shi, Osaka (JP)

(21) Appl. No.: 18/713,353

(22) PCT Filed: Nov. 25, 2022
(86) PCT No.: PCT/JP2022/043514

§ 371 Date: May 24, 2024

(30) Foreign Application Priority Data
Nov. 26, 2021 (JP) 2021-192474

(51) Int. Cl. C23C 16/27; C23C 16/50; H01J 37/32

(52) U.S. Cl. CPC C23C 16/27; C23C 16/50; H01J 37/32715; H01J 2237/3321

(57) ABSTRACT

An embodiment of the present invention provides a diamond formation device comprising: a reaction vessel in which a raw material liquid containing a carbon source is held and a substrate is placed in the raw material liquid; and an electrode part capable of generating plasma in the raw material liquid, wherein the substrate has at least one recess on a main surface on a side facing the electrode part. In addition, an embodiment of the present invention also provides a diamond-coated substrate comprising: a substrate having at least one recess on a main surface; and diamond directly formed on the main surface of the substrate.

### TECHNICAL FIELD

The present invention relates to a diamond formation device and a diamond-coated substrate.

### BACKGROUND ART

Conventionally, a vapor phase synthesis method has been known as a method for forming diamond. Among gas phase synthesis methods, there is a plasma method using plasma, and as one of the methods, an “in-liquid plasma chemical vapor deposition method” in which plasma is generated in a liquid using high frequencies, microwaves, or the like has been proposed. An attempt has already been made to generate plasma in a raw material liquid containing a carbon source by such an in-liquid plasma chemical vapor deposition method, thereby forming diamond on a substrate (see Patent Document 1).

### PRIOR ART DOCUMENTS

### Patent Document

Patent Document 1: JP-A-2008-150246
Non-patent Document 1: Interlayers Applied to CVD Diamond Deposition on Steel Substrate, Djoille Denner Damm, Andre Contin, et al., Coatings 2017, 7, 141

### SUMMARY OF THE INVENTION

### Problems to be Solved by the Invention

Here, in an aspect in which an in-liquid plasma chemical vapor deposition method is used, it is said to be a conventional usual method to separately provide an intermediate layer on a substrate, specifically, a substrate containing iron as a main component, or to form diamond after seeding of fine diamond (see Non-patent Document 2). Among them, in particular, in order to provide an intermediate layer on a substrate, it is necessary to adjust various formation conditions, and it is difficult to stably and repeatedly form an intermediate layer in which a predetermined quality is ensured. Therefore, from the viewpoint of production efficiency, it is desired to form diamond without separately providing an intervening material such as an intermediate layer.

Therefore, an object of the present invention is to provide a diamond formation device capable of directly forming diamond on a substrate and a diamond-coated substrate obtained with the device.

### Solutions to the Problems

In order to solve the above-mentioned object, in an embodiment of the present invention, a diamond formation device comprising: a reaction vessel in which a raw material liquid containing a carbon source is held and a substrate is placed in the raw material liquid; and an electrode part capable of generating plasma in the raw material liquid, wherein the substrate has at least one recess on a main surface on a side facing the electrode part is provided.

In order to solve the above-mentioned object, in an embodiment of the present invention, a diamond-coated substrate comprising: a substrate having at least one recess on a main surface; and diamond directly formed on the main surface of the substrate is provided.

### Effects of the Invention

According to an embodiment of the present invention, it is possible to obtain a diamond-coated substrate in which diamond is directly formed on a substrate.

### BRIEF DESCRIPTION OF THE DRAWINGS

FIG. 1 is a cross-sectional view schematically showing a diamond formation device according to an embodiment of the present invention.

FIG. 2 is a cross-sectional view schematically showing a diamond formation device according to an embodiment of the present invention in a plasma generation state.

FIG. 3 is a plan view schematically showing diamond directly formed on a substrate.

FIG. 4 is a cross-sectional view schematically showing diamond directly formed on a substrate.

FIG. 5A is a cross-sectional view schematically showing an aspect in which a substrate is subjected to cutting.

FIG. 5B is a plan view schematically showing a substrate after cutting.

FIG. 5C is a cross-sectional view schematically showing a diamond formation device according to an embodiment of the present invention in which a substrate with a recess is placed.

FIG. 6 is a cross-sectional view schematically showing a state in which a sintered body constituted by a sub-component of a substrate is provided on a main surface of the substrate.

FIG. 7 is a cross-sectional view schematically showing a state in which carbon is attached to a surface of a sub-component (chromium and/or nickel, or the like) located on a main surface of a substrate.

FIG. 8 is a cross-sectional view schematically showing a state in which plasma is provided on a main surface side of a substrate with a recess.

FIG. 9 is a cross-sectional view schematically showing a state in which diamond is hardly peeled off from a substrate.

FIG. 10 is a plan view schematically showing a diamond formation device according to another embodiment of the present invention.

FIG. 11 is a schematic cross-sectional view taken along line I-I′ in FIG. 10.

FIG. 12A is a side view schematically showing a drill used for forming a recess of a substrate which is a constituent element of a diamond formation device according to an embodiment of the present invention.

FIG. 12B is a photographic view of a drill used for forming a recess of a substrate which is a constituent element of a diamond formation device according to an embodiment of the present invention.

FIG. 13 is SEM images (a) to (c) ((b) and (c) correspond to enlarged SEM images in a circled region in (a)) and a Raman spectrum (d) of a substrate surface in Comparative Example 1 (when a substrate, in which a main surface on a side facing an electrode part was ground with sandpaper, was used).

FIG. 14 is SEM images (a) to (c) ((b) and (c) correspond to enlarged SEM images in a circled region in (a)) and a Raman spectrum (d) of a substrate surface in Comparative Example 2 (when a substrate, in which a main surface on a side facing an electrode part was ground with a metal file, was used).

FIG. 15 is SEM images (a) to (c) ((b) and (c) correspond to enlarged SEM images in a circled region in (a)) and a Raman spectrum (d) of a substrate surface in Comparative Example 3 (when a substrate, in which a main surface on a side facing an electrode part was ground with a flat drill, was used).

FIG. 16 is SEM images (a) to (c) ((b) and (c) correspond to enlarged SEM images in a circled region in (a)) and a Raman spectrum (d) of a substrate surface in Example 1 (when a substrate, in which a main surface on a side facing an electrode part was cut with a drill with a tip angle of 118°, was used) (a version in which diamond was formed in an edge region defining an opening portion of a recess of the substrate).

FIG. 17 is an SEM image of a substrate surface in Example 1 (when a substrate, in which a main surface on a side facing an electrode part was cut with a drill with a tip angle of 118°, was used) (a version in which diamond was formed in an edge region defining an opening portion of a recess of the substrate).

FIG. 18 is SEM images (a) to (c) ((b) and (c) correspond to enlarged SEM images in a circled region in (a)) and a Raman spectrum (d) of a substrate surface in Example 2 (when a substrate, in which a main surface on a side facing an electrode part was cut with a drill with a tip angle of 118°, was used) (a version in which diamond was also formed on a main surface of a substrate extending from an edge region defining an opening portion of a recess of the substrate).

FIG. 19 is SEM images (a) to (c) ((a) 30 times, (b) 500 times, (c) 2000 times/(b) and (c) correspond to enlarged SEM images in a circled region in (a)) and a Raman spectrum (d) of a substrate surface in Example 3 (when a substrate, in which a main surface on a side facing an electrode part was cut with a drill with a tip angle of 118°, was used).

FIG. 20 is SEM images (a) to (c) ((a) 30 times, (b) 500 times, (c) 2000 times/(b) and (c) correspond to enlarged SEM images in a circled region in (a)) and a Raman spectrum (d) of a substrate surface in Example 4 (when a substrate, in which a main surface on a side facing an electrode part was plastically deformed by being pressed against a cemented carbide with a tip angle of 70°, was used).

FIG. 21 is SEM images (a) to (c) ((a) 30 times, (b) 500 times, (c) 2000 times/(b) and (c) correspond to enlarged SEM images in a circled region in (a)) and a Raman spectrum (d) of a substrate surface in Example 5 (when a substrate, in which a chip obtained by scraping a main surface on a side facing an electrode part with a metal file in advance was pressed by being sandwiched with a vise to plastically deform the main surface, was used).

FIG. 22 is SEM images (a) to (c) ((a) 30 times, (b) 500 times, (c) 2000 times/(b) and (c) correspond to enlarged SEM images in a circled region in (a)) and a Raman spectrum (d) of a substrate surface in Comparative Example 4 (when a substrate, in which a main surface on a side facing an electrode part is untreated, was used).

FIG. 23 is a graph showing a relationship between an α value and a β value in each of Examples 3 to 5 and Comparative Example 4.

### DETAILED DESCRIPTION

### [Diamond Formation Device]

Hereinafter, a diamond formation device according to an embodiment of the present invention will be described with reference to the drawings.

### (Basic Configuration of Diamond Formation Device)

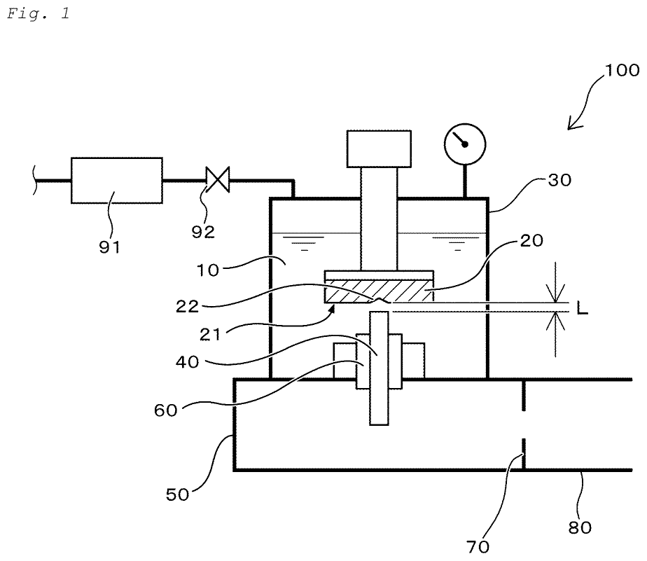

First, before a characteristic part of the present invention is described, a basic configuration of a diamond formation device will be described. FIG. 1 is a cross-sectional view schematically showing a diamond formation device according to an embodiment of the present invention. As shown in FIG. 1, a diamond formation device 100 according to an embodiment of the present invention includes a reaction vessel 30 in which a raw material liquid 10 containing a carbon source is held and a substrate 20 is placed in the raw material liquid 10, and an electrode part 40 capable of generating plasma in the raw material liquid 10.

As the raw material liquid 10 containing a carbon source, for example, an alcohol solution can be used. As the alcohol solution, a combination of methanol and ethanol may be used as an example. Although the alcohol solution is not particularly limited, 70 to 99 vol % or more of methanol and 1 to 30 vol % of ethanol can be used.

The substrate 20 is a member serving as a base for forming diamond on a surface (mainly a main surface) thereof, and is held by a substrate holding part inside the reaction vessel 30. The substrate holding part is disposed so as to extend from the upper portion (or the upper lid) of the reaction vessel 30 to the inside. As will be described later, the substrate 20 usable in the present invention may be a steel (that is, an alloy steel) containing a certain amount or more of an alloy element other than iron and carbon.

As the reaction vessel 30, for example, a quartz vessel can be used. In addition, the reaction vessel 30 may be in a sealed state. The reaction vessel 30 in a sealed state can be decompressed by a decompressor 91 via a regulating valve 92 in order to reduce energy loss during diamond formation using plasma.

The electrode part 40 has alumina, Teflon (registered trademark), or the like as an insulating part 60 therearound. The electrode part 40 may be a metal (for example, aluminum, tungsten, or the like) conductor, and is preferably constituted by a pair of electrodes arranged so as to sandwich the substrate 20 from the viewpoint of facilitating generation of plasma.

In the electrode part 40, one end of the longitudinal axis is located on the raw material liquid side, and the other end is connected to a resonator 50. A microwave or the like generated from an electromagnetic wave generator can be introduced into the resonator 50 from a waveguide 80 through a coupling window 70. A microwave or the like forms bubbles by heat generated at the tip of the metal conductor as the electrode part 40, and high-temperature (about 3000° C.) plasma may be generated in the bubbles.

After plasma is generated, the raw material liquid 10 is partially vaporized between the generated plasma and the substrate 20 facing the plasma, and a low-temperature gas containing a carbon source of the raw material liquid 10 is generated. As the carbon source is deposited on a main surface of the substrate 20, given diamond is formed on the substrate 20 side.

From the viewpoint of making it easy to suitably provide a carbon source necessary for forming diamond by plasma on the substrate 20 side, the electrode part 40 is positioned vertically below (or vertically above) and adjacent to the substrate 20 so as to be able of face the substrate 20. In this case, a distance L between the electrode part 40 and the substrate 20 may be 0.5 mm to 3.0 mm, preferably 1.0 mm to 2.5 mm, and more preferably 1.5 mm to 2.0 mm from the viewpoint of direct irradiation of the substrate 20 with generated plasma.

### (Conventional Common Technical Knowledge of Those Skilled in the Art)

In an aspect in which a conventional in-liquid plasma chemical vapor deposition method is used, as a substrate, one containing iron as a main component is generally used. According to common technical knowledge of those skilled in the art, since iron has a property of diffusing carbon atoms contained in a raw material liquid into the inside thereof, it is known that a carbon component easily penetrates between iron lattices inside the substrate without staying on the surface of the substrate. Therefore, an intervening material such as an intermediate layer constituted by a bonded body of carbon and a metal component (a transition metal element such as chromium, titanium, vanadium, nickel, molybdenum, or tungsten), which is considered to be less likely to be oxidized than iron, and into which carbon is considered to be less likely to penetrate than iron, or a seeding material of fine diamond has been separately provided to the substrate. A carbon source has been deposited on the separately provided intervening material such as an intermediate layer.

### (Motive to Lead to the Present Invention)

In this regard, from the viewpoint of improving the production efficiency of diamond, it is desired to form diamond without separately providing an intervening material such as an intermediate layer, and the inventors of the present application have extensively conducted studies on a method for directly forming diamond on the substrate 20.

### (Characteristic Part of the Present Invention)

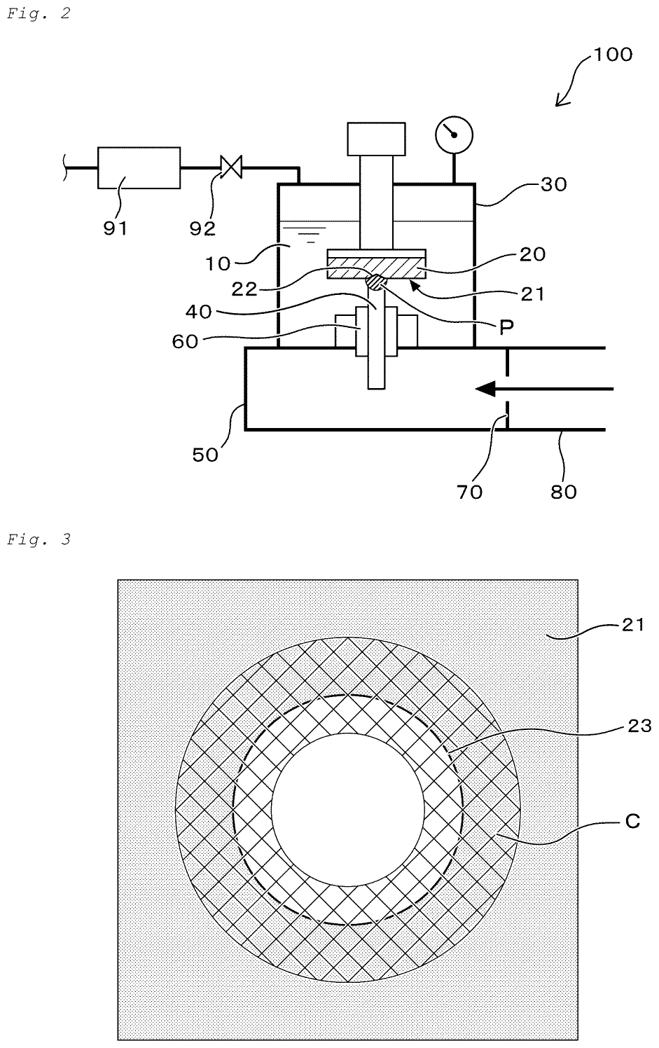

As a result of the studies, the inventors of the present application have newly found that when an in-liquid plasma chemical vapor deposition method is performed using the substrate 20 having at least one recess 22 on the main surface 21 on the side facing the electrode part 40 as shown in FIG. 2, diamond C can be directly formed on the substrate 20 without separately providing an intervening material such as an intermediate layer (see FIGS. 3 and 4). The direct formation of the diamond C on the substrate 20 is an innovative matter compared to the common technical knowledge of those skilled in the art.

More specifically, it has been newly found that the diamond C can be formed at least in an edge region 24 defining an opening portion 23 of the recess 22. The term “recess” as used herein does not refer to a through hole penetrating from one side to the other side, but refers to a depression having an opening portion, and refers to, for example, a depression including a bottom part and a side part extending from the bottom part. In addition, the term “recess” as used herein refers to a depression formed by cutting, plastic deformation, or the like regardless of the size (including diameter and depth) compared to a place of the substrate surface where no recess is formed (that is, a flat surface). Further, the term “recess” as used herein does not include a unidirectionally extending scratched groove only for embedding (seeding) a diamond nucleus in the past, but may include a unidirectionally extending scratched groove for contributing to direct diamond to the substrate without seeding. The term “edge region 24” as used herein refers to a region including not only the edge portion itself but also a peripheral portion thereof (a portion entering the formation region of the recess from the edge portion, or the like). Further, it has been newly found that the diamond C can also be formed on the main surface 21 of the substrate 20 extending from the edge region 24.

### (Mechanism of Direct Formation of Diamond C on Substrate 20)

The inventors of the present application understand that the direct formation of the diamond C on the substrate 20 in the case of using the substrate 20 with the recess 22 has been realized by the following possibilities.

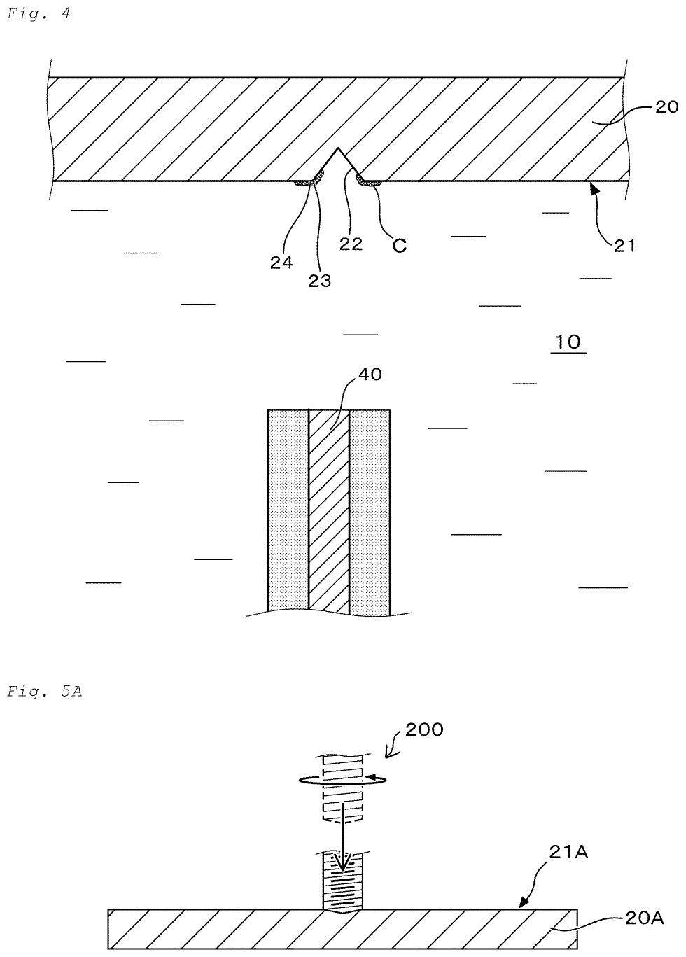

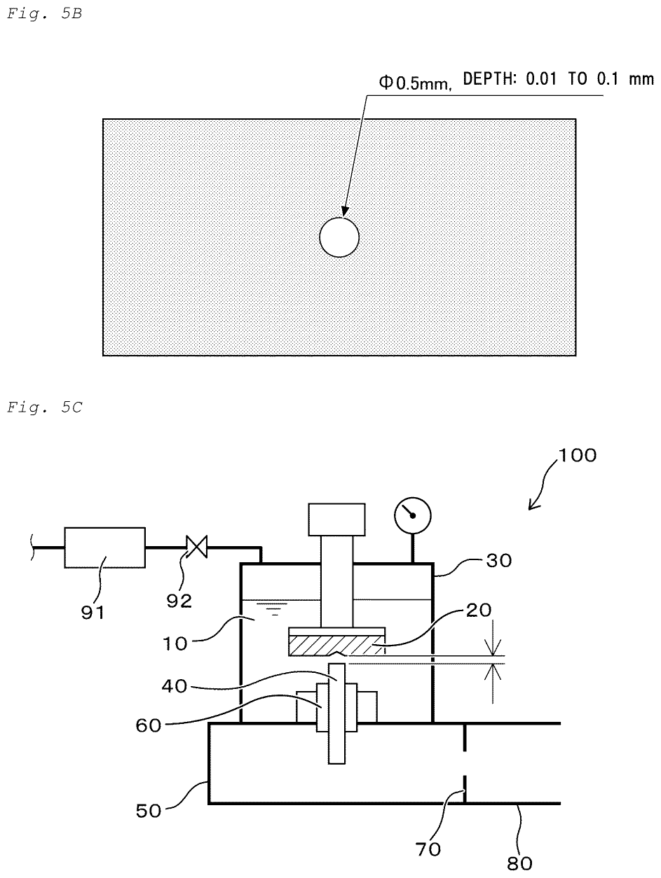

Specifically, first, the diamond formation device 100 according to an embodiment of the present invention including the substrate 20 with the recess 22 can be produced mainly through the following steps. Specifically, as shown in FIG. 5A, cutting (that is, machining) is performed for a main surface 21A of a plate-shaped substrate 20A using a cutting tool such as a drill. The term “drill” as used herein refers to a drill with a tip angle of 40° or more and 160° or less, for example, 90° or more and 140° or less, and may be, for example, a twist drill having a twisted shape on the tip side. The term “drill” as used herein does not include a flat drill with a tip angle of about 180°.

In the present invention, the substrate to be used may be a steel containing a certain amount or more of an alloy element other than iron and carbon (that is, an alloy steel). Specifically, the substrate may contain a material of a transition metal element. For example, the substrate may contain a material of at least one element selected from the group consisting of iron, chromium, nickel, copper, molybdenum, and tungsten. As an example, the substrate may be a stainless steel containing iron as a main component and chromium as a sub-component, for example, SUS403 or SUS430. As another example, the substrate may be a stainless steel containing iron as a main component and chromium/nickel as sub-components, for example, SUS304.

The substrate 20 with the recess 22 can be obtained by performing this cutting. Since the drill used in this case does not include a flat drill with a tip angle of about 180°, the recess 22 after cutting has a shape tapered toward the inside of the substrate 20 (that is, a shape that becomes gradually thinner toward the tip) in a cross-sectional view (see FIG. 4). Further, the recess 22 may have a rectangular shape, a square shape, a perfect circular shape, an elliptical shape, or a polygonal shape in a plan view (see FIG. 5B).

Thereafter, as shown in FIG. 5C, the substrate 20 with the recess 22 is held by the substrate holding part inside the reaction vessel 30 thereby being placed in the reaction vessel 30. Specifically, the substrate 20 is placed such that the tip of the electrode part 40 capable of generating plasma and at least the recess 22 of the substrate 20 can directly face each other. In this state, plasma is provided to the substrate 20 according to the in-liquid plasma chemical vapor deposition method.

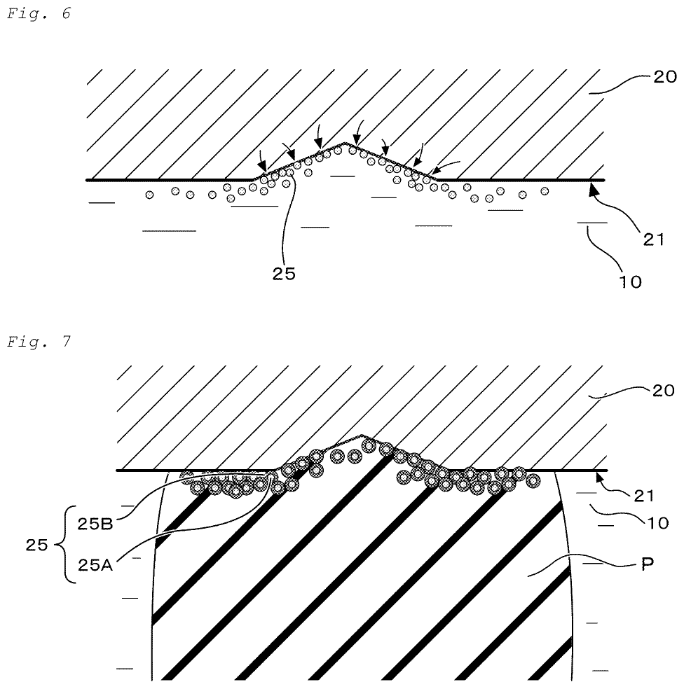

Here, the inventors of the present application understand that the following state is realized by cutting. Specifically, since cutting heat of about 100° C. to 300° C. is generated at the time of cutting using a drill or the like, there is a possibility that a sub-component that is a constituent material of the substrate 20 partially melts and appears on the main surface 21 side, and the sub-component appearing is provided as a sintered body 25 on the main surface 21 of the substrate 20 by subsequent cooling (see FIG. 6).

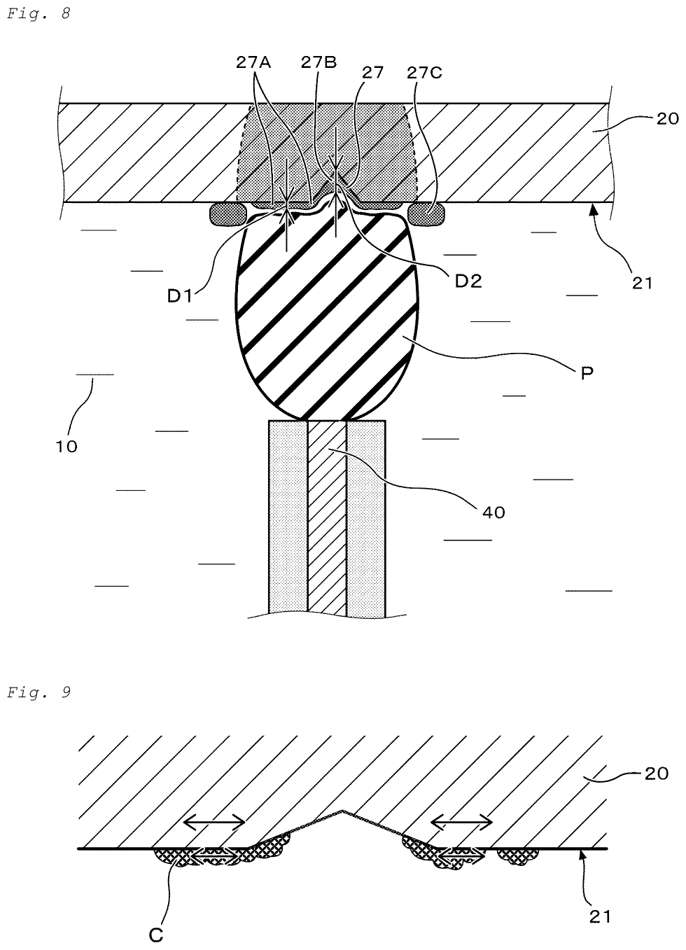

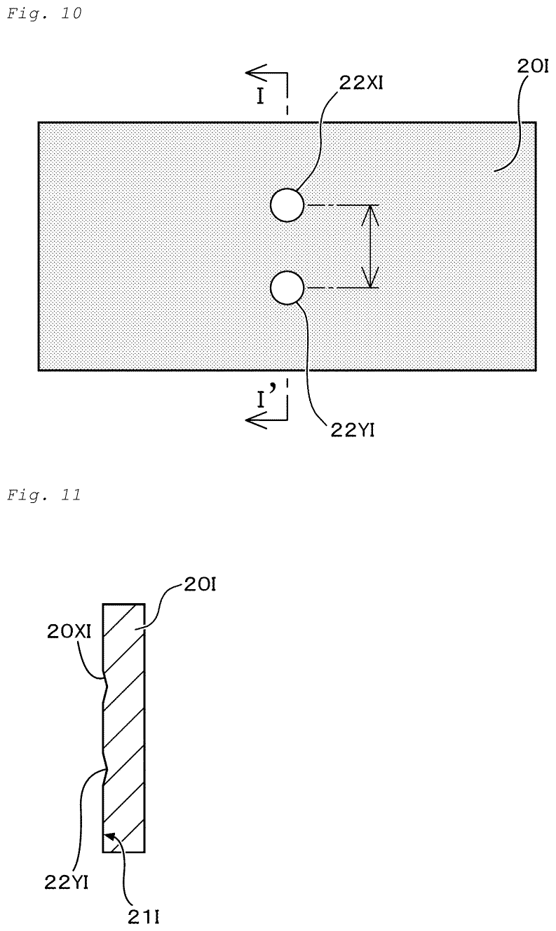

In particular, when the substrate 20 contains carbon, chromium, and/or nickel as a sub-component, chromium and/or nickel captures and retains a carbon atom on the surface thereof, while iron has a property of diffusing a carbon atom into the inside thereof. Therefore, as shown in FIG. 7, it is understood that the sintered body 25 is in a state in which a carbon component 25B tends to stay on the surface of a chromium and/or nickel component 25A as a sub-component.

In view of such a state, although not bound by any specific theory, the inventors of the present application understand that a bonded body (or a sintered body) containing chromium and/or nickel and carbon attached to the surface thereof can function as an intermediate layer and/or a seed of fine diamond as referred in the past. That is, the sintered body may contain amorphous carbon as an intermediate layer or the like.

Thus, as described above, it is understood that the diamond C can be finally formed directly on the substrate 20 without separately forming an intermediate layer or the like as in the past. The inventors of the present application understand that the sintered body containing chromium and/or nickel and carbon attached to the surface thereof is mainly located in the formation region of the recess 22 of the substrate 20 and the periphery of the formation region. This is based on the fact that the proportion at which so-called cutting chips are scattered in the formation region of the recess 22 and the periphery thereof during cutting is high.

(Mechanism of Formation of Diamond in Edge Region Defining Opening Portion of Recess (and Main Surface of Substrate Extending from the Edge Region))

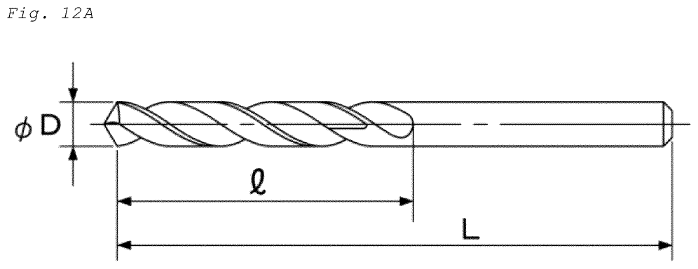

Further, in a case where plasma P is provided on the main surface 21 side of the substrate 20 as shown in FIGS. 7 and 8 in a state where the sintered body containing chromium and/or nickel and carbon attached to the surface thereof is formed on the main surface 21 of the substrate 20 in this manner, at least the carbon source of the raw material liquid 10 located between the plasma P and the substrate 20 may be changed to a low-temperature gas 27 by heat of about 3000° C. of the plasma P. Specifically, as shown in FIG. 8, between the plasma P and the substrate 20, the low-temperature gas 27 derived from the carbon source may be constituted by a relatively thin region 27A and relatively thick regions 27B and 27C.

The inventors of the present application have also found that there is a difference in the thickness of the low-temperature gas 27 derived from the carbon source in a state where the sintered body containing chromium and/or nickel and carbon is formed. More specifically, the diamond C is in a state of being easily formed in the relatively thin region 27A of the low-temperature gas using the sintered body containing chromium and/or nickel and carbon attached to the surface thereof as an active nucleus.

In this regard, a distance D1 between the interface between the relatively thin region 27A and the surface of the substrate 20 and a portion opposite to the interface (or a distance between the interface and the plasma P at a high temperature) is smaller than a distance D2 between the interface between the relatively thick region 27B or 27C and the surface of the substrate 20 and a portion opposite to the interface (or a distance between the interface and the plasma P at a high temperature).

Although not bound by any specific theory, it is understood that this difference in distance relates to a difference in conductivity of heat of the plasma P to the interface between a local region of the low-temperature gas and the surface of the substrate 20, and relates to a formation site of the diamond C finally obtained thereby.

From the above, the diamond C can be finally formed at least in the edge region 24 defining the opening portion 23 of the recess 22 as described above. Further, the diamond C can be finally formed also on the main surface 21 of the substrate 20 extending from the edge region 24 (see FIGS. 3 and 4).

As described above, the inventors of the present application understand that the sintered body containing chromium and/or nickel and carbon attached to the surface thereof, which may be formed by cutting the substrate 20, contributes to the final diamond formation.

However, the present invention is not limited thereto, and when the substrate 20 with a recess is produced in advance with a mold, a die, or the like, there may be a possibility that the difference itself in the thickness of the low-temperature gas 27 derived from the carbon source of the raw material liquid is more important than the formation itself of the sintered body containing chromium and/or nickel and carbon attached to the surface thereof by cutting.

More specifically, there may be a possibility that the relatively thin region 27A of the low-temperature gas is more involved in the contribution to the formation of the diamond C than the formation itself of the sintered body containing chromium and/or nickel and carbon attached to the surface thereof.

### (Mechanism Involved in Difficulty in Peeling of Diamond C)

Further, in a diamond formation process, the substrate 20 is heated by the plasma P until the opposite main surface side reaches about 600° C. to 700° C. In this regard, in a conventional aspect, since the expansion coefficient of iron, which is the main component of the substrate 20, is different from the expansion coefficient of diamond, when iron shrinks in a process of lowering the temperature of the substrate 20 after the irradiation with the plasma P is stopped, it is difficult for diamond to follow the shrinking iron. Therefore, diamond is easily peeled off from the substrate.

On the other hand, in an embodiment of the present invention, a sintered body containing cobalt/nickel as a sub-component of the substrate is formed on the main surface 21 of the substrate 20, and cobalt/nickel has a property that the carbon source of diamond is more likely to be attached to the surface thereof than iron (that is, the affinity between cobalt/nickel and the carbon source is good). Therefore, when cobalt/nickel shrinks in the process of lowering the temperature of the substrate 20 after the irradiation with the plasma P is stopped, diamond is more likely to follow shrinking cobalt/nickel than iron.

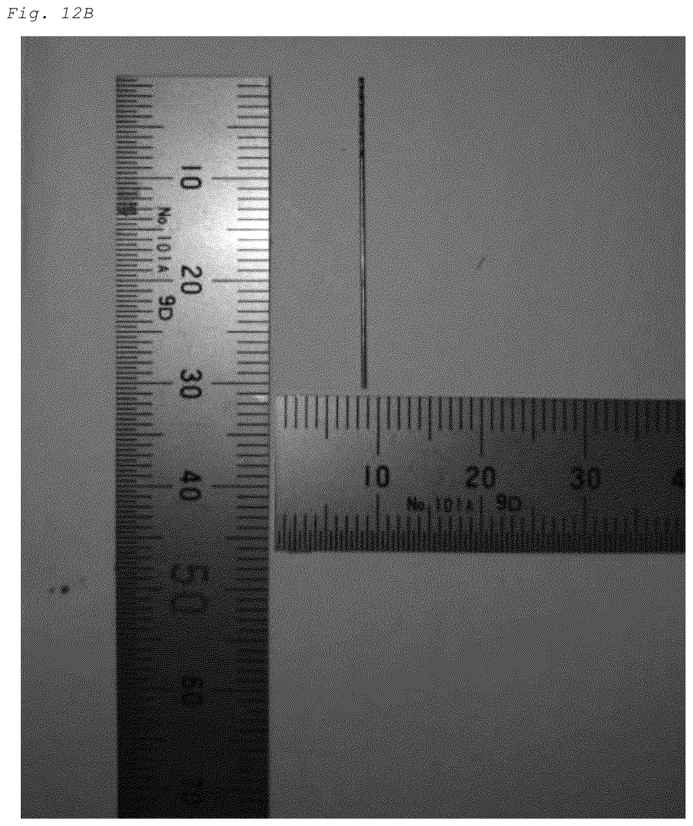

The formation region of the recess 22 of the substrate 20 is a space region. Therefore, it is understood that the formation region of the recess 22 is a region that serves as a stress relaxation point in the substrate 20 and is relatively less likely to shrink than a given region of the substrate 20 having no recess. From the above, the diamond C is hardly peeled off from the substrate 20 as shown in FIG. 9.

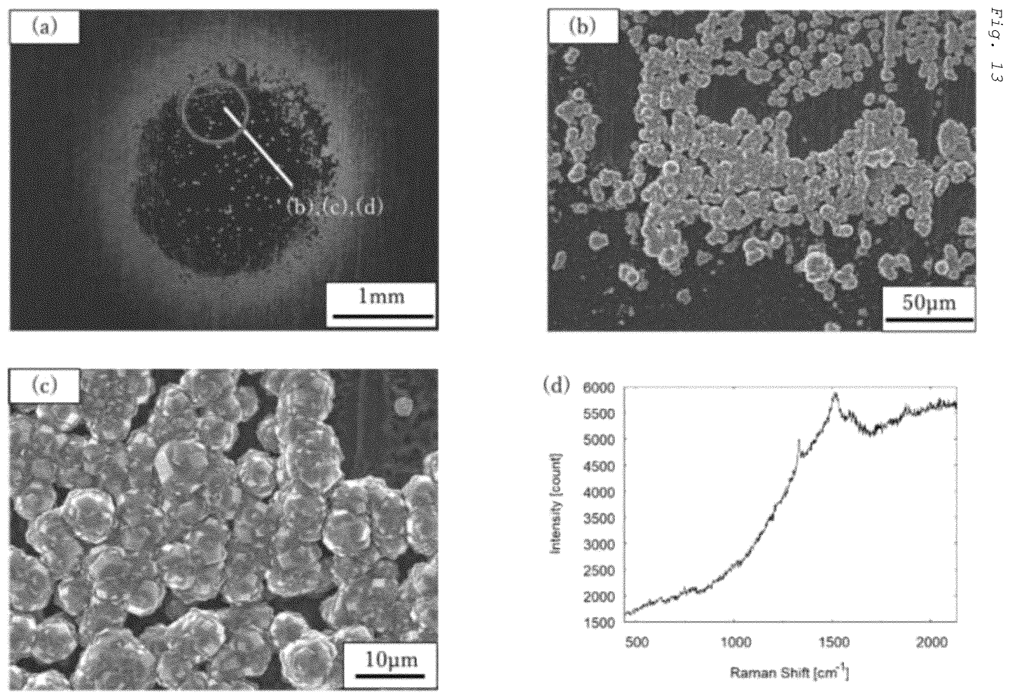

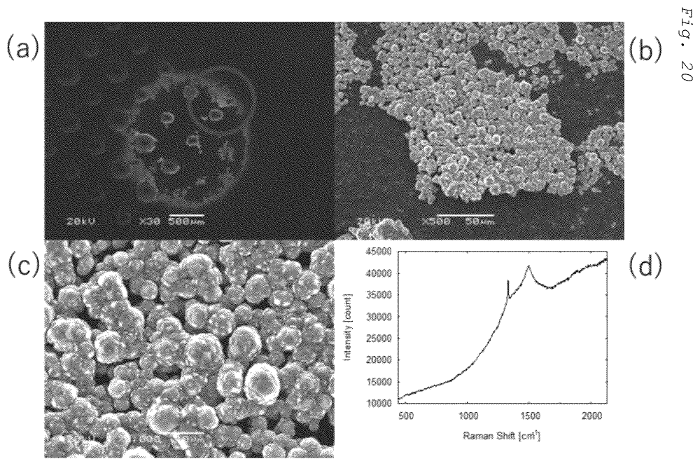

In the above description, explanation is made based on the assumption that the number of recesses 22 of the substrate 20 is one. However, the number of recesses 22 may be two or more. In this case, as shown in FIGS. 10 and 11, at least a first recess 22XI and a second recess 22YI disposed separately from the first recess 22XI may be provided. In this case, in an embodiment of the present invention, diamond extending along a main surface 211 of a substrate 201 may be formed between the first recess 22XI and the second recess 22YI (see FIG. 18).

### [Diamond-Coated Substrate]

Hereinafter, a configuration of a diamond-coated substrate formed using the diamond formation device 100 having the above-mentioned characteristic configuration will be described. Since the characteristic configuration of the substrate 20 has already been described above, the description thereof will be simplified below.

As described above, it has been found that when an in-liquid plasma chemical vapor deposition method is performed using the diamond formation device 100 according to an embodiment of the present invention, the diamond C can be directly formed on the substrate 20 (see FIGS. 3 and 4). This makes it possible to take out the diamond-coated substrate from the reaction vessel 30 of the diamond formation device 100 after the in-liquid plasma chemical vapor deposition method is performed.

Specifically, the diamond-coated substrate includes the substrate 20 having at least one recess 22 on the main surface 21, and the diamond C directly formed on the main surface 21 of the substrate 20 (see FIGS. 4, 16, 18, and the like). The term “diamond-coated substrate” as used herein refers to a substrate directly coated (or directly covered) with diamond, and can also be referred to as “a substrate with diamond”, “a composite of diamond and a substrate”, and/or “an integrated material of diamond and a substrate”.

As already described above, the substrate 20 and the recess 22 of the substrate 20, which are constituent elements of the diamond-coated substrate, have the following characteristics.

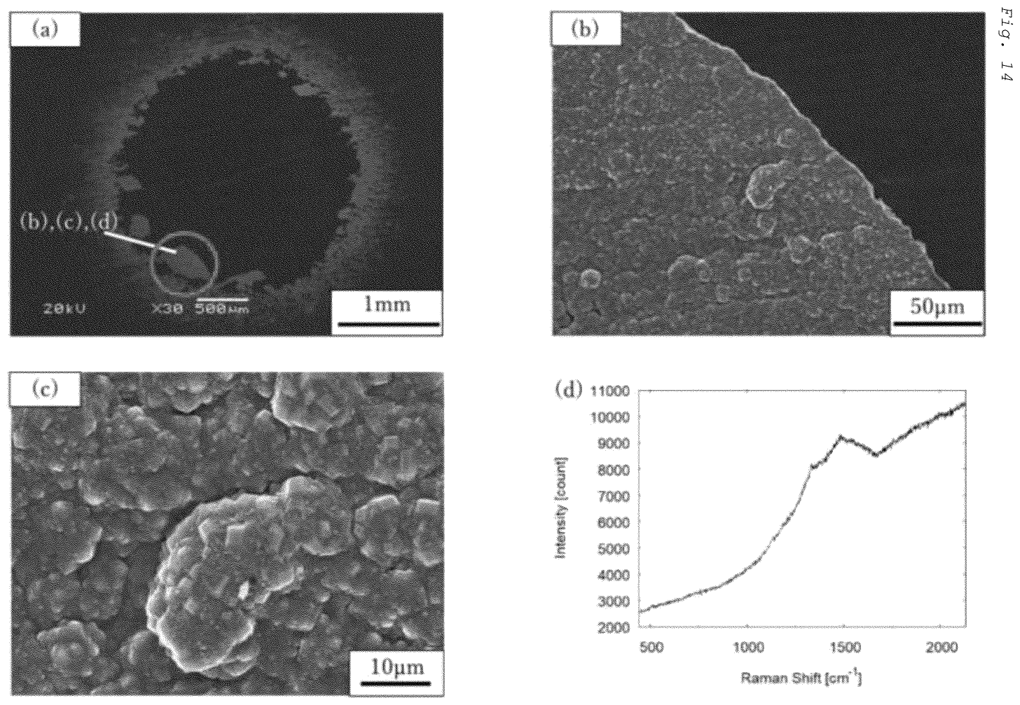

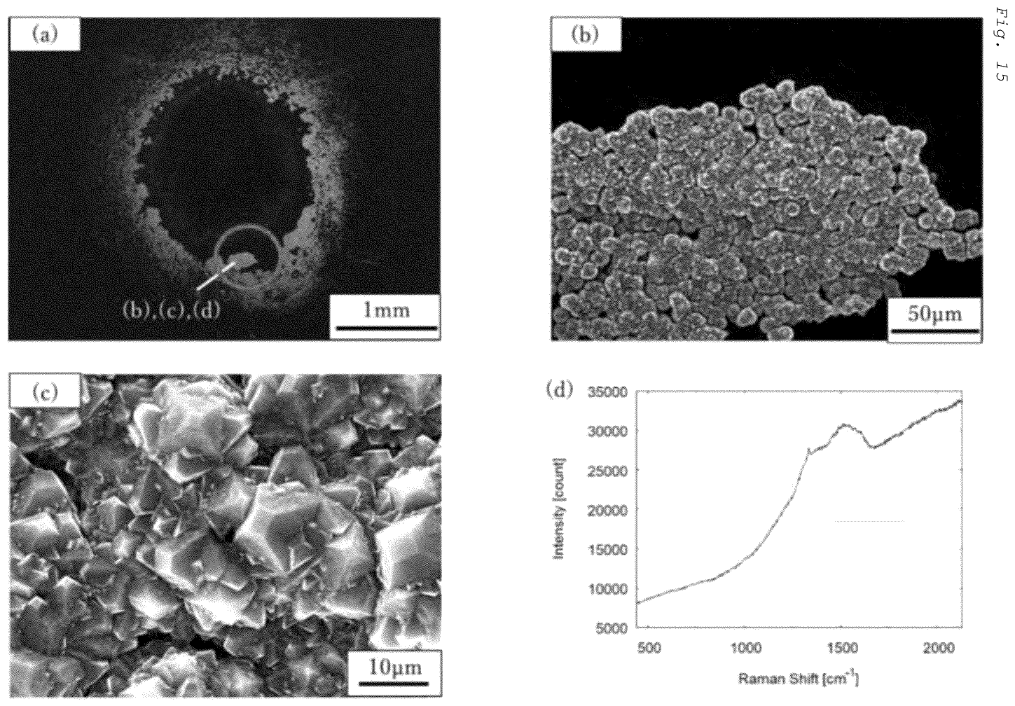

In one embodiment, the recess 22 of the substrate 20 can be formed by cutting using a drill with a tip angle of 40° or more and 160° or less (see FIGS. 5A, 12A, and 12B). When the recess is formed by cutting, the recess 22 of the substrate 20 may have a tapered shape in a cross-sectional view (see FIG. 4 and the like). In addition, in this case, the recess 22 of the substrate 20 may have a rectangular shape, a square shape, a perfect circular shape, an elliptical shape, or a polygonal shape in a plan view (see FIG. 5B). The recess 22 of the substrate 20 can also be formed by plastic deformation of the main surface of the substrate 20.

The diamond C is formed in the edge region 24 defining the opening portion 23 of the recess 22 of the substrate 20 (see FIGS. 3, 4, 16, and 17). The diamond C is further formed also on the main surface 21 of the substrate 20 extending from the edge region 24 (see FIGS. 3, 4, and 18).

When at least the first recess 22XI and the second recess 22YI disposed separately from the first recess 22XI are provided, diamond extending along the main surface 211 of the substrate 201 is formed between the first recess 22XI and the second recess 22YI (see FIGS. 10, 11, and 18).

The substrate 20 contains a material of a transition metal element. The substrate 20 contains a material of at least one element selected from the group consisting of iron, chromium, nickel, copper, molybdenum, and tungsten. The substrate 20 is an alloy steel. The substrate 20 is a stainless steel.

Although one embodiment of the present invention has been described above, only typical examples of the application range of the present invention have been illustrated. Therefore, a person skilled in the art may easily understand that the present invention is not limited thereto, and various modifications may be made.

### EXAMPLES

Diamond formation was performed by an in-liquid plasma chemical vapor deposition method using the following device.

### Examples 1 and 2

### (Constituent Elements)

A diamond formation device 100 including the following constituent elements was used.
=Raw material liquid 10:
   A methanol solution (97 vol %) and an ethanol solution (3 vol %)
Substrate 20:
One made of a stainless steel (SUS304) was used.
One in which the recess 22 (opening diameter: 0.5 mm, depth: 0.01 to 0.1 mm) was formed by cutting (machining) using a twist drill with a tip angle of 118° (see FIGS. 12A and 12B) was used. The number of recesses 22 was set to 9.

As the twist drill, product number SD (straight shank drill) 0.5 [blade diameter D: 0.5 mm, groove length (1): 7.5 mm, total length L: 30 mm] manufactured by NACHI-FUJIKOSHI CORP. (NACHI) was used.

Since a drill with a tip angle of 118° was used, the cross-sectional shape of the recess 22 formed in the substrate was a tapered shape, and the planar shape of the recess 22 was a circular shape.

The distance between the opening centers of the respective recesses was set to 1.0 mm.

Diamond originally prepared in this recess 22 was used as a push-in pedestal.

### Reaction Vessel 30:

One (inner diameter: 94 mm, height: 100 mm), which was formed of a cylindrical quartz glass and a stainless steel flange, and in which airtightness was maintained, was used.

### Electrode Part 40:

One constituted by an electrode having a diameter of 4 mm and obtained using tungsten as a material was used.
Insulating part 60 around electrode part 40: PTFE (Teflon (registered trademark))

### (Implementation Procedure)

The electrode part 40 was disposed below the reaction vessel 30, and then the raw material liquid 10 was poured into the reaction vessel 30. Thereafter, an upper lid constituting a part of the reaction vessel with a substrate holding part holding the substrate 20 was placed so that the substrate 20 was disposed separate from and facing the electrode part 40. The separation and facing distance was adjusted to 1.5 mm. After the substrate 20 was disposed, a decompressor (aspirator) was operated to decompress the inside of the reaction vessel 30. After decompression, a microwave of 2.5 GHz was applied through the waveguide 80 (WRJ-2 waveguide) to generate plasma between a recess of the electrode part 40 and the substrate 20. The diameter of the plasma was 4 to 6 mm. Thereafter, the pressure was adjusted to 40 kPa by the regulating valve 92.

### Example 3

Plasma was generated under the same conditions as in Example 1. In this example, the separation and facing distance between the substrate 20 and the electrode part was set to 2.0 mm, and a microwave of 2.45 GHz was used. The other conditions were the same as in Example 1.

### Example 4

Unlike Example 1, a substrate with a recess formed through plastic deformation by pressing a cemented carbide having a diameter of 4 mm and a tip angle of 70° against the main surface of the substrate 20 on the side facing the electrode part was used. Further, in this example, the separation and facing distance between the substrate 20 and the electrode part was set to 2.0 mm, and a microwave of 2.45 GHz was used. The other conditions were the same as in Example 1.

### Example 5

Unlike Example 1, the surface of the substrate 20 was scraped with a metal file in advance to form a chip, and the chip was pressed against and attached to the surface of the substrate 20 by sandwiching the substrate 20 with the chip with a vise. The substrate surface was plastically deformed by pressing the chip to form a recess on the surface. In this example, the substrate with this recess was used. In this example, the separation and facing distance between the substrate 20 and the electrode part was set to 2.0 mm, and a microwave of 2.45 GHz was used. The other conditions were the same as in Example 1.

### Comparative Example 1

A substrate, in which a main surface of the substrate 20 on a side facing the electrode part was ground with a sandpaper, and the ground powder generated by the grinding was removed, was used. The other conditions were the same as in Example 1.

### Comparative Example 2

A substrate, in which a main surface of the substrate 20 on a side facing the electrode part was ground with a metal file, and the ground powder generated by the grinding was removed, was used. The other conditions were the same as in Example 1.

### Comparative Example 3

A substrate, in which a main surface of the substrate 20 on a side facing the electrode part was ground with a flat drill (diameter: 6 mm) with a tip angle of 180°, and the ground powder generated by the grinding was removed, was used. The other conditions were the same as in Example 1.

### Comparative Example 4

An untreated substrate not subjected to processing such as cutting was used. In this comparative example, the separation and facing distance between the substrate 20 and the electrode part was set to 2.0 mm, and a microwave of 2.45 GHz was used. The other conditions were the same as in Example 1.

### (Measurement Details)

A deposit on the substrate in each of Examples 1 to 5 and Comparative Examples 1 to 4 after the in-liquid plasma chemical vapor deposition method was performed was observed with a scanning electron microscope (SEM), and a Raman spectrum was measured.
Scanning electron microscope (SEM) (manufactured by JEOL Ltd./product name: JSM-6060)
Microscopic Raman spectrometer (manufactured by RENISHAW Corporation/product name: inVia Reflex, excitation light (150 mW), spot diameter: 1.4 μm, YAG laser wavelength: 532 nm)

In the measurement, a deposit (film) on the substrate surface, in which a peak of diamond (peak at 1333 cm⁻¹ representing sp³) appeared by Raman spectroscopy, was evaluated as diamond.

Further, in Examples 3 to 5 and Comparative Example 4, an α value that quantifies the deposition area of the deposit on the substrate and a β value that quantifies the quality of the deposit (corresponding to diamond) were calculated.

The “α value” as used herein is a value obtained by cutting out an SEM image in a circular shape in a range hit by plasma, binarizing the image into white and black for each pixel using Open Source Computer Vision Library (OpenCV), and quantifying the ratio of white pixels (corresponding to the area of the deposited portion of the deposit) to the total pixels.

The “β value” as used herein is a value obtained by determining a linear approximation formula of the background of fluorescence of the Raman spectrum (excluding 1100 cm⁻¹ to 1700 cm⁻¹), calculating the distance to the diamond peak (1333 cm⁻¹) and the distance to the G peak (1550 cm⁻¹) for graphite based on the linear approximation formula, and quantifying the ratio of the two values.

### (Measurement Results)

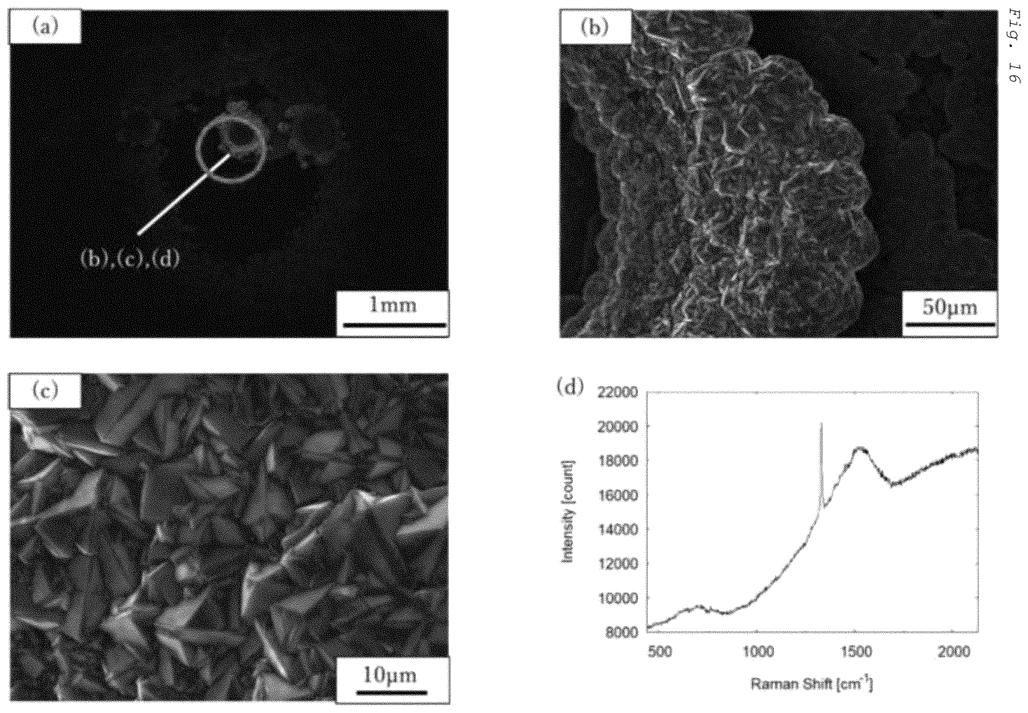

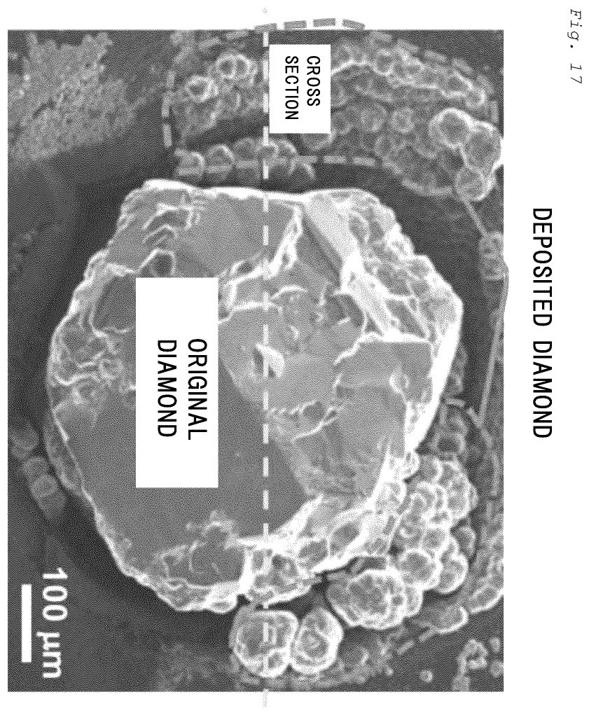

In Comparative Examples 1 to 3, low quality diamond was synthesized. The area where diamond was formed was also small. When an experiment was performed under the same conditions a plurality of times, most of the deposit on the substrate was amorphous carbon. The probability of becoming diamond was about 10% (see FIGS. 13 to 15).

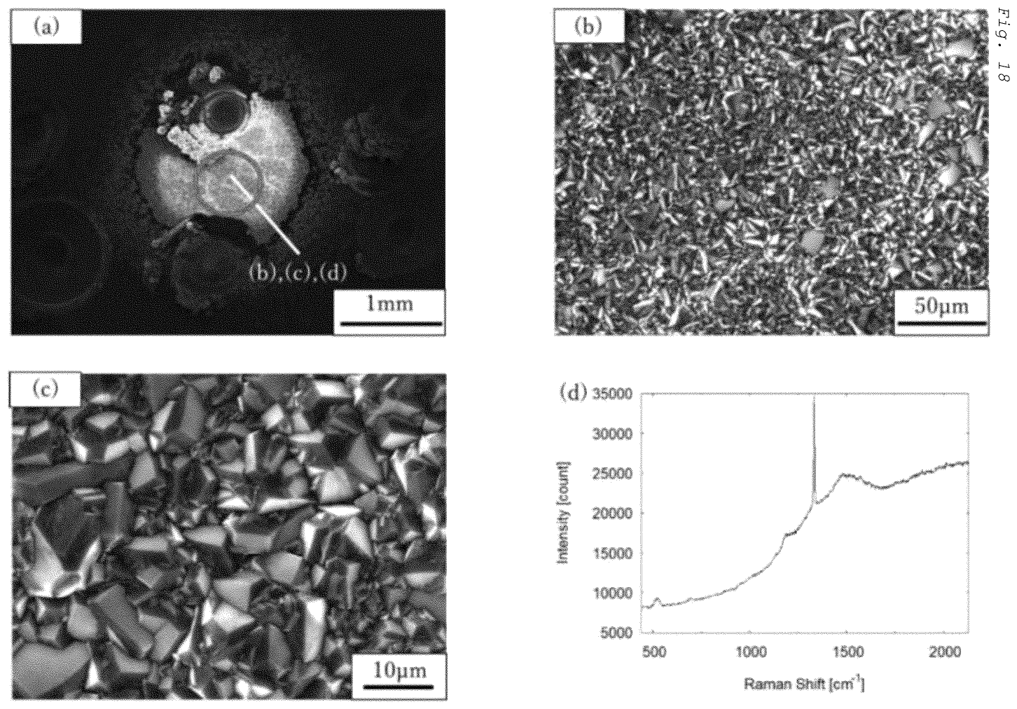

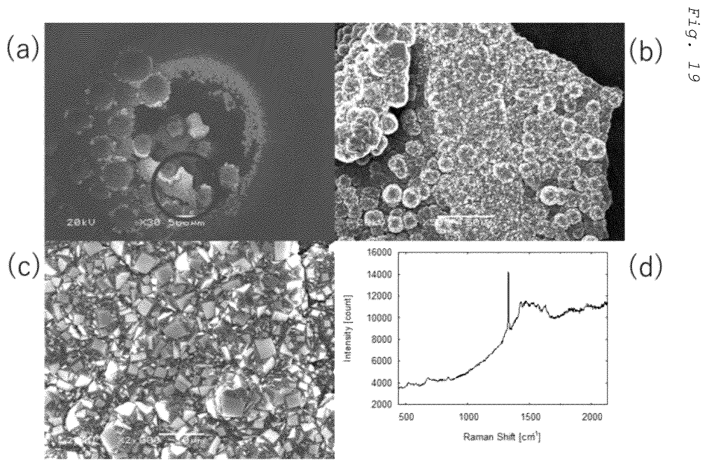

In Examples 1 and 2, high-quality diamond was formed in a wider range than in Comparative Examples 1 to 3. As a result of performing the experiment under the same conditions a plurality of times, the probability of forming diamond was about 50%. In Example 1, diamond was formed in an edge region defining the opening portion of the recess 22 of the substrate 20 (see FIGS. 16 and 17). Further, in Example 2, diamond was also formed on the main surface 21 (specifically, a portion not processed with a drill between adjacent recesses) of the substrate 20 extending from this edge region (see FIG. 18).

From the above results, it was found that as compared with the case of grinding the substrate surface in Comparative Examples 1 to 3, in the case of forming the recess 22 by scraping the substrate surface in Examples 1 and 2, high-quality diamond can be formed without separately providing an intermediate layer or performing seeding of fine diamond in the past. As a result, after the in-liquid plasma chemical vapor deposition method was performed, a diamond-coated substrate including a substrate having a recess on a main surface and diamond directly formed on the main surface of the substrate could be taken out from the reaction vessel of the diamond formation device.

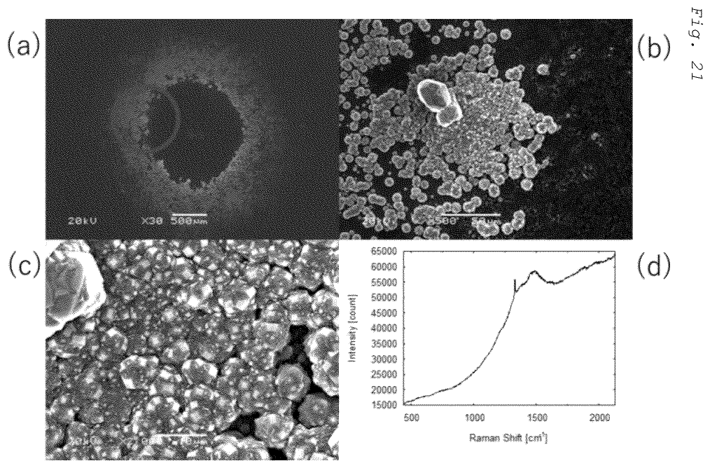

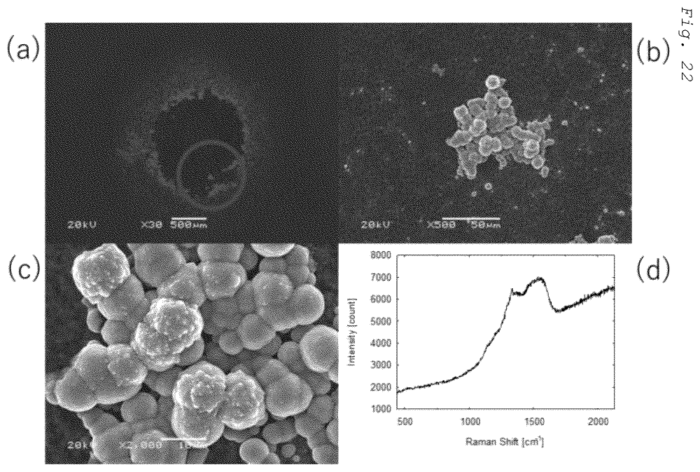

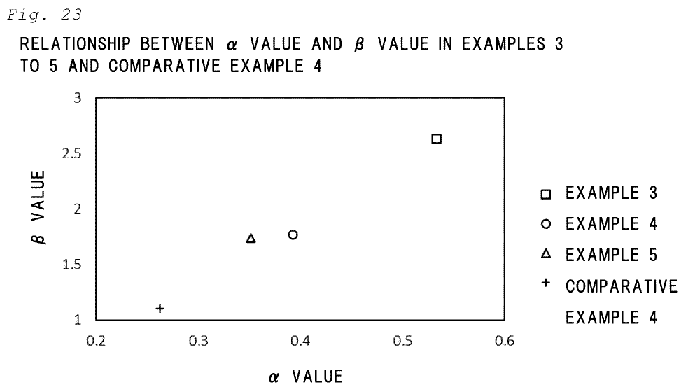

Further, in Examples 3 to 5 (see FIGS. 19 to 21) and Comparative Example 4 (see FIG. 22), the measured values of the α value and the β value were as shown in Table 1 below (see FIG. 23). In Example 3, diamond was also formed in an edge region defining the opening portion of the recess of the substrate and on the main surface (specifically, a portion not processed with a drill between adjacent recesses) of the substrate extending from the edge region (see FIG. 19).

TABLE 1

| | α value | β value |
|---|---|---|
| Example 3 | 0.53 | 2.63 |
| Example 4 | 0.39 | 1.77 |
| Example 5 | 0.35 | 1.74 |
| Comparative Example 4 | 0.26 | 1.11 |

From Table 1 and FIG. 23, both the α value and the β value of the deposit obtained by generating plasma between the recess formed on the substrate surface and the electrode part 40 in each of Examples 3 to 5 were higher than the α value and the β value of the deposit (diamond) obtained by generating plasma between the untreated substrate and the electrode part 40 in Comparative Example 4. That is, it was found that the formation area of the diamond obtained in each of Examples 3 to 5 was larger than that in Comparative Example 4, and the quality of the diamond obtained in each of Examples 3 to 5 was higher than that in Comparative Example 4. From this, it was found that a substrate with a recess contributes to an increase in the formation area and improvement in quality of diamond deposited on the substrate.

In this regard, although not bound by any specific theory, it can be considered that Cr and Ni components included in the constituent components of the substrate (SUS304) were exposed on the substrate surface along with the formation of the recess on the substrate surface by cutting or plastic deformation in Examples 3 to 5. In Comparative Example 4, the Cr and Ni components are stably combined with oxygen (O) in the air on the surface of the untreated substrate. On the other hand, in Examples 3 to 5, due to the scratch on the substrate surface by plastic deformation or cutting, the bond between the Cr or Ni component and oxygen (O) is weakened and the Cr and Ni components may become unstable. In this unstable state, when the carbon (C) component in the raw material liquid 10 is decomposed by generation of plasma and supplied, the Cr and Ni components can be bonded to the carbon component by eliminating oxygen (O). It is understood that this bonded material functions as an intermediate layer, and thereby diamond can be grown, triggered by the intermediate layer, in the edge region defining the opening portion of the recess of the substrate.

When the α values and the β values in Examples 3 to 5 were compared, it was found that the α value was about 0.53 and the β value was about 2.63 in Example 3, and the α and B values were the highest in Examples 3 to 5. Further, in Example 4, the α value was about 0.39 and the β value was about 1.77, whereas in Example 5, the α value was about 0.35 and the β value was about 1.74, and it was found that the α and β values in Example 4 were slightly higher than those in Example 5.

In this regard, although not bound by any specific theory, when a recess is formed by cutting, Cr and Ni components included in the constituent components of the substrate (SUS304) may be more likely to be exposed on the substrate surface due to the processing mode. As a result, it is understood that the bonded material of such a component and the carbon component in the raw material liquid 10 decomposed by plasma can more suitably function as an intermediate layer, thereby allowing more suitable deposition of diamond.

Further, in Example 5, a chip obtained by scraping with a metal file in advance was attached to the recess formed on the surface of the substrate compared to Comparative Example 4. The chip contains Cr and Ni components, but the bond of these components to oxygen (O) is weak due to scraping and the Cr and Ni components may be unstable. Therefore, the Cr and Ni components contained in the chip attached to the substrate surface is bonded to the carbon (C) component in the raw material liquid 10 decomposed by plasma by eliminating this oxygen (O), and a bonded material may be formed. It is understood that diamond can be grown, triggered by this bonded material, at least in the edge region of the substrate.

In addition, also in Example 3, it is conceivable that a chip due to cutting was attached to the recess formed on the surface of the substrate due to cutting compared to Example 4. Therefore, similarly to Example 5, it is also understood that the Cr and Ni components contained in the chip attached to the substrate surface is bonded to the carbon (C) component in the raw material liquid 10 decomposed by plasma by eliminating this oxygen (O), and diamond can be grown, triggered by this bonded material.

In Examples 2, 3, and 5, diamond was also formed on the main surface of the substrate extending from the edge region defining the opening portion of the recess of the substrate. In this regard, it is understood that the bonded material of the Cr or Ni component located in the edge region and the carbon component spreads to the main surface (corresponding to the flat region of the substrate) of the substrate continuous with the edge region, and the Cr or Ni component bonded in a stabilized state to oxygen (O) on the main surface of the substrate is preferentially bonded to the carbon component in the bonded material by eliminating the oxygen (O) component, and diamond can be grown, triggered by this, also in the flat region of the substrate.

Alternatively, it is also understood that a bonded material of the Cr or Ni component located in the edge region and the carbon component spreads to the main surface (corresponding to the flat region of the substrate) of the substrate continuous with the edge region, the carbon component in the bonded material reduces the oxygen (O) component bonded to the Cr or Ni component to form CO, and the Cr or Ni component loses oxygen (O) to become unstable, whereby the unstable Cr or Ni component is bonded to the carbon (C) component in the raw material liquid 10 decomposed by plasma, and diamond can be grown, triggered by this, also in the flat region of the substrate.

Each embodiment is an example, and the present invention is not limited to each embodiment. Further, partial replacement or combination of the configurations shown in different embodiments is possible.

An embodiment of the present invention is as follows.

<1>

A diamond formation device comprising:
a reaction vessel in which a raw material liquid containing a carbon source is held and a substrate is placed in the raw material liquid; and
an electrode part capable of generating plasma in the raw material liquid,
wherein the substrate has at least one recess on a main surface on a side facing the electrode part.
   <2>

The diamond formation device according to <1>, wherein diamond can be directly formed on the main surface of the substrate.

<3>

The diamond formation device according to <1> or <2>, wherein diamond can be formed in an edge region defining an opening portion of the recess.

<4>

The diamond formation device according to <3>, wherein diamond can be further formed on a main surface of the substrate extending from the edge region.

<5>

The diamond formation device according to <4>, wherein the at least one recess includes a first recess and a second recess disposed separately from the first recess, and the diamond extending along a main surface of the substrate is formed between the first recess and the second recess.

<6>

The diamond formation device according to any one of <1> to <5>, wherein the substrate contains a material of a transition metal element.

<7>

The diamond formation device according to <6>, wherein the substrate contains a material of at least one element selected from the group consisting of iron, chromium, nickel, copper, molybdenum, and tungsten.

<8>

The diamond formation device according to any one of <1> to <7>, wherein the substrate is an alloy steel.

<9>

The diamond formation device according to <8>, wherein the substrate is a stainless steel.

<10>

The diamond formation device according to any one of <1> to <9>, wherein the electrode part and the recess of the substrate directly face each other.

<11>

The diamond formation device according to any one of <1> to <10>, wherein the recess has a tapered shape in a cross-sectional view.

<12>

The diamond formation device according to any one of <1> to <11>, wherein the recess has a rectangular shape, a square shape, a perfect circular shape, an elliptical shape, or a polygonal shape in a plan view.

<13>

The diamond formation device according to any one of <1> to <12>, wherein the substrate has the recess provided by cutting using a drill with a tip angle of 40° or more and 160° or less.

<14>

The diamond formation device according to any one of <1> to <10>, wherein the substrate has the recess provided by plastic deformation of the main surface of the substrate.

<15>

A method for forming diamond using the diamond formation device according to any one of <1> to <14>, the method comprising providing the plasma to the substrate in a state where the electrode part capable of generating the plasma and at least the recess of the substrate face each other.

<16>

A diamond-coated substrate comprising:
a substrate having at least one recess on a main surface; and
diamond directly formed on the main surface of the substrate.
   <17>

The diamond-coated substrate according to <16>, wherein the substrate has the recess provided by cutting using a drill with a tip angle of 40° or more and 160° or less.

<18>

The diamond-coated substrate according to <16>, wherein the substrate has the recess provided by plastic deformation of the main surface of the substrate.

<19>

The diamond-coated substrate according to any one of <16> to <18>, wherein the diamond is formed in an edge region defining an opening portion of the recess.

<20>

The diamond-coated substrate according to <19>, wherein diamond is further formed on a main surface of the substrate extending from the edge region.

<21>

The diamond-coated substrate according to <20>, wherein the at least one recess includes a first recess and a second recess disposed separately from the first recess, and the diamond extending along a main surface of the substrate is formed between the first recess and the second recess.

<22>

The diamond-coated substrate according to any one of <16>, <17>, and <19> to <21>, wherein the recess has a tapered shape in a cross-sectional view.

<23>

The diamond-coated substrate according to any one of <16>, <17>, and <19> to <22>, wherein the recess has a rectangular shape, a square shape, a perfect circular shape, an elliptical shape, or a polygonal shape in a plan view.

<24>

The diamond-coated substrate according to any one of <16> to <23>, wherein the substrate contains a material of a transition metal element.

<25>

The diamond-coated substrate according to <24>, wherein the substrate contains a material of at least one element selected from the group consisting of iron, chromium, nickel, copper, molybdenum, and tungsten.

<26>

The diamond-coated substrate according to any one of <16> to <25>, wherein the substrate is an alloy steel.

<27>

The diamond-coated substrate according to <26>, wherein the substrate is a stainless steel.

### INDUSTRIAL APPLICABILITY

The diamond formation device according to an embodiment of the present invention enables the formation of a diamond-coated substrate with high strength (that is, a substrate with diamond).

### CROSS-REFERENCE TO RELATED APPLICATIONS

The present application claims priority under the Paris Convention based on Japanese Patent Application No. 2021-192474 (filing date: Nov. 26, 2021, Title of Invention: “DIAMOND FORMATION DEVICE AND DIAMOND-COATED SUBSTRATE”). The entire contents disclosed in the application are incorporated herein by reference.

### EXPLANATION OF REFERENCES

100 Diamond formation device
10 Raw material liquid
20, 201 Substrate (with recess)
20A Plate-shaped substrate (without recess)
21, 211 Main surface of substrate on side facing electrode part
21A Main surface of plate-shaped substrate
22 Recess
22XI, 22YI Recess
23 Opening portion of recess
24 Edge region defining opening portion of recess
25 Sintered body
25A Chromium and/or nickel component, or the like
25B Carbon component
27 Low-temperature gas derived from carbon source of raw material liquid
27A Relatively thin region of low-temperature gas
27B Relatively thick region of low-temperature gas
27C Relatively thick region of low-temperature gas
30 Reaction vessel
40 Electrode part
50 Resonator
60 Insulating part
70 Coupling window
80 Waveguide
91 Decompressor
92 Regulating valve
C Diamond
D1 Distance between interface between relatively thin region of low-temperature gas and surface of substrate and portion opposite to the interface
D2 Distance between interface between relatively thick region of low-temperature gas and surface of substrate and portion opposite to the interface
P Plasma
L Distance between electrode part and substrate

What is claimed:

1. A diamond formation device comprising:
a reaction vessel in which a raw material liquid containing a carbon source is held and a substrate is placed in the raw material liquid; and
an electrode part capable of generating plasma in the raw material liquid,
wherein the substrate has at least one recess on a main surface on a side facing the electrode part.

2. The diamond formation device according to claim 1, wherein diamond can be directly formed on the main surface of the substrate.

3. The diamond formation device according to claim 1, wherein diamond can be formed in an edge region defining an opening portion of the recess.

4. The diamond formation device according to claim 3, wherein diamond can be further formed on a main surface of the substrate extending from the edge region.

5. The diamond formation device according to claim 4, wherein the at least one recess includes a first recess and a second recess disposed separately from the first recess, and the diamond extending along a main surface of the substrate is formed between the first recess and the second recess.

6. The diamond formation device according to claim 1, wherein the substrate contains a material of a transition metal element.

7. The diamond formation device according to claim 6, wherein the substrate contains a material of at least one element selected from the group consisting of iron, chromium, nickel, copper, molybdenum, and tungsten.

8. The diamond formation device according to claim 1, wherein the substrate is an alloy steel.

9. The diamond formation device according to claim 8, wherein the substrate is a stainless steel.

10. The diamond formation device according to claim 1, wherein the electrode part and the recess of the substrate directly face each other.

11. The diamond formation device according to claim 1, wherein the recess has a tapered shape in a cross-sectional view.

12. The diamond formation device according to claim 1, wherein the recess has a rectangular shape, a square shape, a perfect circular shape, an elliptical shape, or a polygonal shape in a plan view.

13. The diamond formation device according to claim 1, wherein the substrate has the recess provided by cutting using a drill with a tip angle of 40° or more and 160° or less.

14. The diamond formation device according to claim 1, wherein the substrate has the recess provided by plastic deformation of the main surface of the substrate.

15. A method for forming diamond using the diamond formation device according to claim 1, the method comprising providing the plasma to the substrate in a state where the electrode part capable of generating the plasma and at least the recess of the substrate face each other.

16. A diamond-coated substrate comprising:
a substrate having at least one recess on a main surface; and
diamond directly formed on the main surface of the substrate.

17. The diamond-coated substrate according to claim 16, wherein the substrate has the recess provided by cutting using a drill with a tip angle of 40° or more and 160° or less.

18. The diamond-coated substrate according to claim 16, wherein the substrate has the recess provided by plastic deformation of the main surface of the substrate.

19. The diamond-coated substrate according to claim 1, wherein the diamond is formed in an edge region defining an opening portion of the recess.

20. The diamond-coated substrate according to claim 19, wherein diamond is further formed on a main surface of the substrate extending from the edge region.

21. The diamond-coated substrate according to claim 20, wherein the at least one recess includes a first recess and a second recess disposed separately from the first recess, and the diamond extending along a main surface of the substrate is formed between the first recess and the second recess.

22. The diamond-coated substrate according to claim 16, wherein the recess has a tapered shape in a cross-sectional view.

23. The diamond-coated substrate according to claim 16, wherein the recess has a rectangular shape, a square shape, a perfect circular shape, an elliptical shape, or a polygonal shape in a plan view.

24. The diamond-coated substrate according to claim 16, wherein the substrate contains a material of a transition metal element.

25. The diamond-coated substrate according to claim 24, wherein the substrate contains a material of at least one element selected from the group consisting of iron, chromium, nickel, copper, molybdenum, and tungsten.

26. The diamond-coated substrate according to claim 16, wherein the substrate is an alloy steel.

27. The diamond-coated substrate according to claim 26, wherein the substrate is stainless steel.
